(19) United States
(12) Patent Application Publication
(10) Pub. No.: US 2026/0350379 A1
(43) Pub. Date: Nov. 5, 2026

(54) DEVICE AND METHOD FOR CONVERTING A SIGNAL FOR AN ARTIFICIAL NEURON APPLICATION

(71) Applicant: Golana Computing, Grenoble (FR)

(72) Inventors: Ioan-Mihai MIRON, Tullins (FR); Gilles Gaudin, Corenc (FR); Miguel Rubio-Roy, Proveysieux (FR)

(73) Assignee: Golana Computing, Grenoble (FR)

(21) Appl. No.: 19/713,141

(22) Filed: Jun. 18, 2026

Related U.S. Application Data
(63) Continuation of application No. PCT/FR2024/051684, filed on Dec. 16, 2024.

(30) Foreign Application Priority Data
Dec. 21, 2023 (FR) 23/14774

(51) Int. Cl. G06N 3/06

(52) U.S. Cl. CPC G06N 3/06

(57) ABSTRACT

The present disclosure relates to a conversion device for converting an initial signal (SI) into a dataset (SC) including a magnetic component configured to switch between a first magnetic state (M1) and a second magnetic state (M2); a junction member separating the magnetic component into an upstream chamber and a downstream chamber; an excitation unit configured to generate a physical excitation in order to excite the magnetic material, wherein the physical excitation is generated according to the initial signal (SI); a detection unit configured to detect and record at least one triggering characteristic parameter (Nbf), wherein the dataset comprises the at least one triggering characteristic parameter (Nbf). The present disclosure also relates to a classification system comprising such a conversion device, to a conversion method, and to a classification method.

### CROSS-REFERENCE TO RELATED APPLICATIONS

This application is a continuation of International Application No. PCT/FR2024/051684, filed on Dec. 16, 2024, which claims priority to and the benefit of FR23/14774 filed on Dec. 21, 2023. The disclosures of the above applications are incorporated by reference herein.

### FIELD

The present disclosure relates to a classification system intended to classify an input signal into a signal class. This type of classification system is particularly suitable for applications in the development of spiking neural networks, referred to as “in materio computing”. This refers to the use of physical devices for artificially reproducing the behavior of a neural network, using the properties of the considered physical device(s), and in particular of the material(s) they comprise.

The present disclosure also relates to a classification method for classifying an input signal into a signal class, this classification method being implemented by a classification system as previously described.

### BACKGROUND

The statements in this section merely provide background information related to the present disclosure and may not constitute prior art.

There are different ways to artificially reproduce a neural network, for example in the field of photonics, or in the field of spin electronics.

The existing solutions in the field of photonics have made it possible to replicate the behavior of individual elements as well as to demonstrate the functionalities of more complete devices. Nevertheless, these implementations have complex architectures and generally involve high energy consumption.

The existing solutions of the spin electronics are also interesting because they have good endurance relative to photonic systems, and are compatible with CMOS (Complementary Metal Oxide Semi-conductor) technologies.

However, the different solutions have so far been limited to proof-of-concept demonstrations of simple devices and are not suitable for the realization of a functional neuromorphic device.

Document EP4160484A1 discloses such a functional neuromorphic network capable, in particular, of performing speech recognition of spoken digits. This network consists of a set of magnetic devices, each reproducing the behavior of a neuron. In particular, these magnetic devices are configured so as to reproduce the properties of accumulation, loss or leakage, and triggering or “firing”, beyond a certain threshold.

In order to reproduce a complete neuromorphic network, chambers are disposed in multiple rows and separated by gates, all rows are connected to a central nucleation chamber, which serves as the starting point for the propagation of a domain wall. This propagation of the domain wall then occurs when a physical excitation corresponding to the signal to be processed is generated. To achieve this, a magnetic domain of a given orientation is nucleated in the central nucleation chamber. This magnetic orientation is opposite to that of the rest of the magnetic component, thus making it possible to form the domain wall. In this configuration, the physical excitation will result in exciting and moving the magnetic domain wall located at the interface between two domains of opposite magnetizations. Chambers will thus be filled and gates crossed until a network is obtained in which some chambers are in one magnetic orientation and in which the other chambers are in a second magnetic orientation. The obtained image of the complete network is then characteristic of the information to be processed that was used to excite the system.

This solution has the advantage of allowing the processing of a signal without requiring very large computing capacities, particularly for preprocessing calculations and for calculating synaptic weights.

However, in order to obtain a neuromorphic network capable of discriminating a wide variety of signals, it is desired to increase the number of rows of chambers. But, given that the size of a chamber is in the range of 0.1 μm to 10 μm on a side, and that the number of rows can be greater than 10,000, the total surface area of the classification system can quickly become large, or even unsuitable for some applications.

Furthermore, the energy consumption required for the physical excitation by a magnetic field increases with the surface area of the device. When using an electric current as the physical quantity for excitation, the energy consumption increases with the length of the rows.

### SUMMARY

This section provides a general summary of the disclosure and is not a comprehensive disclosure of its full scope or all of its features.

One or more forms of the present disclosure may address all or part of the aforementioned issues.

One or more forms of the present disclosure may provide a compact and energy-efficient solution making it possible to reproduce a complete neuromorphic network.

This aim can be achieved thanks to the implementation of a conversion device to convert an initial signal into a dataset, the conversion device comprising: a magnetic component comprising a magnetic material configured to vary locally between a first magnetic state having a first magnetization, and a second magnetic state having a second magnetization different from the first magnetization, said magnetic component being subdivided into a plurality of regions, where each region is either in the first magnetic state or in the second magnetic state; each region in the first magnetic state being separated from a region in the second magnetic state by a magnetic domain wall; a junction member separating the magnetic component between an upstream chamber and a downstream chamber and providing a magnetic communication between the upstream chamber and the downstream chamber, said junction member being characterized by a magnetic transmission value corresponding to a capacity of the junction member to allow a displacement of the magnetic domain wall in a direction of propagation, said direction of propagation being defined from the upstream chamber to the downstream chamber; an initialization unit configured to place the magnetic component in an initial magnetic configuration, in which the magnetic domain wall is disposed at the junction member; an excitation unit configured to generate a physical excitation in order to excite the magnetic material, so as to move the magnetic domain wall in the direction of propagation, the physical excitation being generated as a function of the initial signal; a detection unit disposed at the downstream chamber, said detection unit being configured to detect and record at least one characteristic triggering parameter when a physical parameter associated with a deformation state of the magnetic domain wall exceeds a predetermined threshold value, the dataset comprising said at least one characteristic triggering parameter.

The previously described provisions make it possible to provide a conversion device capable of converting an initial signal into a dataset comprising one or several characteristic triggering parameters. This type of device is particularly well-suited for artificial neural applications. Furthermore, the use of only two chambers makes it possible to obtain a more compact conversion device requiring less electrical energy input.

The term “magnetic transmission value” means the ability of the junction member to allow transmission of a magnetic domain wall. In other words, this “magnetic transmission value” corresponds to the inverse of the resistance that the junction member can produce when passing through a magnetic domain wall.

The term “magnetic domain wall” means an interface separating two regions of the same continuous magnetic medium that are not in the same magnetic state.

The conversion device may also have one or several of the following characteristics, taken alone or in combination.

According to one form, the conversion device comprises a nucleation member configured to place the magnetic component in a magnetic nucleation configuration, in which all regions of the magnetic component are placed in the first magnetic state, except for one nucleation region which is placed in the second magnetic state, said nucleation region being contained in the upstream chamber.

In general, the magnetic material of the magnetic component is inhomogeneous. In other words, in most configurations, the magnetic component comprises a plurality of regions, where at least one region of the plurality of regions is in the first magnetization state, and where at least one other region of the plurality of regions is in the second magnetization state.

According to one form, the initialization unit comprises the nucleation member.

According to one form, the physical parameter associated with a deformation state of the magnetic domain wall is a distance measured in the direction of propagation from the junction member, the characteristic triggering parameter being detected and recorded by the detection unit when this distance exceeds a predetermined threshold distance.

Alternatively, the physical parameter associated with a deformation state of the magnetic domain wall is a measurement of surface area or a surface-area ratio, the characteristic triggering parameter being detected and recorded by the detection unit when this surface area or this surface-area ratio exceeds the predetermined threshold value.

According to one form, the dataset is a number corresponding to the number of times a characteristic triggering parameter is recorded by the detection unit. In other words, the dataset is equal to the sum of the detected characteristic triggering parameters.

According to one form, the excitation unit is configured to stop at least temporarily the physical excitation of the magnetic material when the following condition is met: at least one characteristic triggering parameter is detected by the detection unit.

The ability to select the threshold value beyond which a characteristic triggering parameter is detected makes it possible to detect this characteristic triggering parameter even when the domain wall has not completely filled the downstream chamber. It is therefore possible to passively return to the initial configuration when the excitation unit temporarily stops the physical excitation of the magnetic material. In this way, it is possible to artificially reproduce a succession of chambers.

According to one form, the conversion device further comprises a closed-contour peripheral boundary in which the magnetic component is entirely contained.

Thus, it is possible to limit the expansion of the domain wall when it meets the peripheral boundary.

Generally, the peripheral boundary is a non-magnetic region. For example, a groove etched into the material consisting the magnetic component, or a region that has been subjected to irradiation by a laser beam or ionic radiation making it possible to form said non-magnetic region.

According to one form, the peripheral boundary is quadrilateral. Thus, the manufacture of the conversion device is simplified.

According to one form, the initialization unit is configured to place the magnetic component in the initial magnetic configuration when the following condition is met: the at least one characteristic triggering parameter is detected by the detection unit.

The ability to reset the magnetic component by placing it in the initial magnetic configuration after each detection of a characteristic triggering parameter makes it possible to accelerate the return of the magnetic component in the initial magnetic configuration, this makes it possible to detect temporally a maximum number of characteristic triggering parameters by the conversion device. Furthermore, this makes it possible to artificially reproduce a conversion device including a succession of chambers.

According to one form, the initialization unit comprises an expansion member configured to move the magnetic domain wall up to the junction member, so as to place the magnetic component in the initial magnetic configuration.

Thus, it is possible to place the conversion device in a configuration where the physical excitation generated by the excitation unit only contributes to moving the magnetic domain wall beyond the junction member into the downstream chamber.

According to one form, the initialization unit comprises the excitation unit, the excitation unit being configured to move the magnetic domain wall up to the junction member, so as to place the magnetic component in the initial magnetic configuration.

According to one form, the conversion device further comprises a reconfiguration unit configured to modify the magnetic transmission value of the junction member.

Thus, it is possible to modify the magnetic transmission value of the junction member to adapt it to the initial signal that one wishes to convert.

According to one form, the reconfiguration unit is configured to modify the magnetic transmission value of the junction member each time the detection unit detects a characteristic triggering parameter.

Thus, it is possible to modify the magnetic transmission value of the junction member when the magnetic component is placed in the initial magnetic configuration. This makes it possible to artificially reproduce a succession of chambers separated by junction members with varying magnetic transmission values. In other words, the junction member is reconfigurable.

According to one form, the excitation unit comprises a current generator configured to generate an electric current.

Synergistically, using a current generator as an excitation unit in a conversion device with only two chambers makes it possible to reduce the energy consumption of the system while maintaining good conversion quality of the initial signal by the conversion device.

According to one form, the physical excitation corresponds to a signal comprising pulses of electric current.

The aim of the present disclosure can also be achieved thanks to the implementation of a classification system intended to classify an input signal into a signal class, the classification system comprising: at least one preprocessing device intended to transform the input signal into at least one initial signal; at least one conversion device as described above and taking as input an initial signal from said at least one initial signal and converting said initial signal taken as input into a dataset; an identification unit taking as input the dataset and configured to associate the input signal with a signal class as a function of the dataset, said signal class being selected from a set of predetermined signal classes recorded in a memory of the classification system.

The provisions described above make it possible to provide a classification system capable of classifying an input signal as a function of the response detected by the conversion device.

According to one form, the classification system comprises at least two conversion devices.

According to one form, the classification system comprises at least two conversion devices taking as input the same initial signal or each a distinct initial signal obtained by transforming the same input signal by means of a distinct preprocessing device.

For example, the classification system may take as input a single input signal and may comprise one or several preprocessing devices. The preprocessing device(s) may convert the input signal into an identical initial signal for all conversion devices, or alternatively into a plurality of distinct initial signals, which may or may not be distinct for each conversion device. In other words, the same input signal may be preprocessed differently by the preprocessing device for each conversion device.

In this way, it is possible to perform at least two conversions of the initial signal into a dataset, to improve the conversion of the signal.

The aim of the present disclosure can also be achieved thanks to the implementation of a method for converting an initial signal into a dataset, the conversion method being implemented by a conversion device as described above, and comprising the following phases: an initialization phase comprising an initial step in which the magnetic component is placed in the initial magnetic configuration; an excitation phase in which the excitation unit generates the physical excitation as a function of the initial signal, so as to move the magnetic domain wall; a reconfiguration phase implemented if the detection unit detects that the at least one physical parameter associated with the deformation state of the magnetic domain wall exceeds the predetermined threshold value, the reconfiguration phase then comprising a detection step in which the detection unit records at least one characteristic triggering parameter in the dataset.

The provisions described above make it possible to provide a conversion method for converting an initial signal into a dataset by a conversion device which may use only two chambers of a magnetic material.

It is therefore well understood that the excitation phase is implemented continuously, and that several detection steps can be implemented, in particular each time the at least one physical parameter associated with the deformation state of the magnetic domain wall exceeds the predetermined threshold value.

The conversion method may also have one or several of the following characteristics, taken alone or in combination.

According to one form, the initial signal and the physical excitation are time-dependent. In this case, the conversion method may be stopped at the temporal end of the physical excitation.

According to one form, the initialization unit is configured to place the magnetic component in the initial magnetic configuration, for example through the expansion member.

According to one form, the initialization unit comprises a nucleation member, the initialization phase then comprising a nucleation step, implemented before the initial step, in which the nucleation member places the magnetic component in the magnetic nucleation configuration in which all regions of the magnetic component are placed in the first magnetic state, except for one nucleation region which is placed in the second magnetic state, said nucleation region being contained in the upstream chamber.

Thus, it is possible to prepare the conversion device to carry out a conversion, especially when it has not been used for a long time.

According to one form, the initial step is implemented simultaneously with the excitation phase. In other words, it is the physical excitation generated during the excitation phase that makes it possible to move the domain wall towards the junction member so as to pass from the nucleation magnetic configuration to the initial magnetic configuration.

According to one form, the initial magnetic configuration corresponds to a configuration where the inhomogeneous magnetic material is in the second magnetic state in the upstream chamber, and in the first magnetic state in the downstream chamber, or vice versa.

According to one form, the reconfiguration phase is implemented when the magnetic material present in the downstream chamber is entirely in the second magnetic state.

Thus, detecting when the magnetic wall exceeds the threshold distance is simpler.

According to one form, the reconfiguration phase comprises a stop step, in which the excitation unit stops at least temporarily the implementation of the excitation phase; a new excitation phase being implemented at the end of the reconfiguration phase.

Stopping the excitation phase allows the magnetic component to return to the initial magnetic configuration before implementing the excitation phase again.

According to one form, a new initialization phase is implemented at the end of the reconfiguration phase.

Thus, it is possible to place the magnetic component in the initial magnetic configuration, even when the downstream chamber is entirely in the second magnetic state. It is also possible to actively return the magnetic component to the initial magnetic configuration to save time.

According to one form, the reconfiguration phase further comprises a modification step implemented after the detection step, in which the reconfiguration unit modifies the magnetic transmission value of the junction member.

In this way, it is possible to artificially reproduce a succession of chambers separated by junction members having a varying magnetic transmission value.

The aim of the present disclosure can also be achieved thanks to the implementation of a classification method for classifying an input signal into a signal class, the classification method being implemented by a classification system as described above and comprising the following steps: a preprocessing step in which the preprocessing device transforms the input signal into at least one initial signal; at least one conversion step in which a conversion method as described above is applied by the conversion device to an initial signal from said at least one initial signal, so as to obtain a dataset corresponding to said initial signal to which the conversion method is applied; an identification step in which the identification unit associates the input signal with a signal class as a function of the dataset obtained during the at least one conversion step.

The provisions described above make it possible to provide a method for classifying an input signal into a signal class through a compact conversion device.

According to one form, the preprocessing step may comprise transforming the input signal into a plurality of initial signals. Each initial signal of the plurality of initial signals may be identical to or different from another of the initial signals. Thus, during each conversion step, each conversion device applies the conversion method to its associated initial signal.

In this way, it is possible to preprocess the input signal differently during the preprocessing step, as a function of the characteristics that one wishes to extract from the input signal, or as a function of the conversion device that will apply the conversion method to the initial signal thus preprocessed.

Further areas of applicability will become apparent from the description provided herein. It should be understood that the description and specific examples are intended for purposes of illustration only and are not intended to limit the scope of the present disclosure.

### DRAWINGS

In order that the disclosure may be well understood, there will now be described various forms thereof, given by way of example, reference being made to the accompanying drawings, in which:

FIG. 1 is a schematic view of a classification system according to a particular form of the present disclosure;

FIGS. 2A-2F is a schematic view illustrating different ways of implementing a nucleation step, through a nucleation member;

FIGS. 3A-3F is a schematic view of a conversion device according to a particular form of the present disclosure implementing certain steps of the conversion method;

FIG. 4 is a schematic perspective view of a conversion device according to a particular form of the present disclosure, and illustrating more particularly the detection unit;

FIG. 5 is a graph representing the evolution of the physical parameter associated with a deformation state of the domain wall, as a function of time;

FIG. 6 is a schematic side and top view of a conversion device according to a particular form of the present disclosure comprising a fixed junction member;

FIG. 7 is a schematic side and top view of a conversion device according to a particular form of the present disclosure comprising a reconfigurable junction member;

FIGS. 8A-8B is a schematic view illustrating different ways of implementing a modification step, through a reconfiguration unit;

FIGS. 9A-9C is a schematic view illustrating different ways of implementing a modification step, through a reconfiguration unit;

FIG. 10 is a schematic view illustrating some steps of the initialization phase;

FIG. 11 is a schematic view of a classification method according to a particular form of the present disclosure; and

FIG. 12 is a schematic view of a classification method according to a particular form of the present disclosure.

The drawings described herein are for illustration purposes only and are not intended to limit the scope of the present disclosure in any way.

### DETAILED DESCRIPTION

The following description is merely exemplary in nature and is not intended to limit the present disclosure, application, or uses. It should be understood that throughout the drawings, corresponding reference numerals indicate like or corresponding parts and features.

In the figures and in the remainder of the description, the same reference represents identical or similar elements. In addition, the different elements are not drawn to scale to provide clarity of the figures. Moreover, the different forms and variants are not mutually exclusive and can be combined with each other.

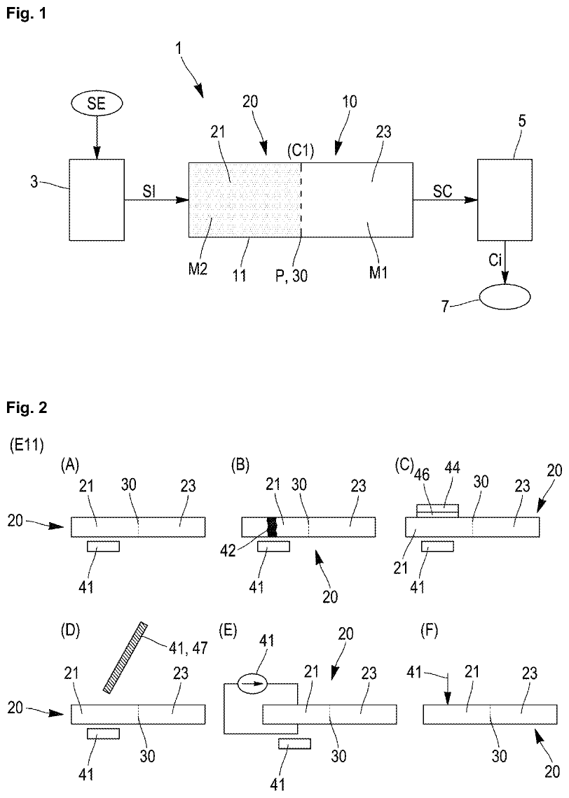

As illustrated in FIGS. 1 to 9, the present disclosure relates to a conversion device 10 for converting an initial signal, denoted “SI”, into a dataset, denoted “SC”. For example, the initial signal SI may correspond to an input signal, denoted “SE”, that has been preprocessed by a preprocessing device 3, which will be described later. The input signal SE may correspond to information to be processed, which is preprocessed into an initial signal SI that can be converted by the conversion device 10. For example, and without limitation, the input signal SE may be preprocessed as a succession of pulses, as described in European patent application No. 22315278.6 filed in November 2022. Alternatively, the initial signal SI may correspond to a variation in amplitude, frequency, time response, or any other type of signal making it possible to excite a magnetic material.

The conversion device first comprises a magnetic component 20, which comprises a magnetic material configured to vary locally between a first magnetic state, denoted “M1” having a first magnetization, and a second magnetic state, denoted “M2” having a second magnetization different from the first magnetization. As can be seen in FIG. 1, the conversion device 10 may comprise a closed-contour peripheral boundary 11 in which the magnetic component 20 is entirely contained. Thus, and as will be presented later, it is possible to limit the expansion of a magnetic domain wall P when it encounters the peripheral boundary 11. Generally, the peripheral boundary 11 is a non-magnetic region, for example, a groove etched into the material constituting the magnetic component 20, a region that has been subjected to irradiation by a laser beam, or an ion irradiation enabling the formation of said non-magnetic region. It is also possible, but not limited to, such a peripheral boundary 11 being quadrilateral. Thus, the manufacture of the conversion device 10 is simplified.

The magnetic component 20 is subdivided into a plurality of regions, where each region is either in the first magnetic state M1 or in the second magnetic state M2. Each region in the first magnetic state M1 is separated from a region in the second magnetic state M2 by a magnetic domain wall P. The term “magnetic domain wall P” means an interface separating two regions of the same continuous magnetic medium that are not in the same magnetic state. Generally, the magnetic material of the magnetic component 20 is inhomogeneous. In other words, in most configurations, the magnetic component 20 comprises a plurality of regions, where at least one region of the plurality of regions is in the first magnetic state M1, and where at least one other region of the plurality of regions is in the second magnetic state M2.

The conversion device 10 also comprises a junction member 30 separating the magnetic component 20 between an upstream chamber 21 and a downstream chamber 23. FIG. 1 represents in particular a form in which the upstream chamber 21 is entirely in the second magnetic state M2, and in which the downstream chamber 23 is entirely in the first magnetic state M1. The junction member provides a magnetic communication between the upstream chamber 21 and the downstream chamber 23, said junction member 30 being characterized by a magnetic transmission value denoted “Rtr” corresponding to the capacity of the junction member 30 to allow a displacement of the magnetic domain wall P in a direction of propagation denoted “X”, said direction of propagation X is defined from the upstream chamber 21 to the downstream chamber 23. The term “magnetic transmission value Rtr” means the capacity of the junction member 30 to allow the transmission of a magnetic domain wall P. In other words, this “magnetic transmission value Rtr” corresponds to the inverse of the resistance that the junction member 30 can produce in the passage of a magnetic domain wall P. Generally, the propagation of the magnetic domain wall P within one of the two chambers 21 or 23 is easier than its propagation through the junction member 30. The junction member 30 therefore acts as a gate constituting a brake on the propagation of the magnetic domain wall P between the upstream chamber 21 and the downstream chamber 23.

The conversion device 10 also comprises an initialization unit 40 configured to place the magnetic component 20 in an initial magnetic configuration denoted “C1”, in which the magnetic domain wall P is disposed at the junction member 30. Such an initial magnetic configuration C1 is represented for example in FIG. 1.

According to one form, the conversion device 10 comprises a nucleation member 41 configured to place the magnetic component 20 in a magnetic nucleation configuration denoted C0, in which all regions of the magnetic component 20 are placed in the first magnetic state M1, except for one nucleation region which is placed in the second magnetic state M2, said nucleation region being contained within the upstream chamber 21. It is also possible that the initialization unit 40 comprises the nucleation member 41. FIG. 2 illustrates different variants of nucleation members 41. Placing the magnetic component 20 in the magnetic nucleation configuration C0 is particularly useful in the case where the entire conversion device 10 is in the first magnetic state M1. In this case, the nucleation member 41 makes it possible to form a region in the second magnetic state M2, and thus create a magnetic domain wall P.

FIG. 2A illustrates a nucleation member 41 configured to apply a local magnetic field to form the nucleation region. Generally, a nucleation member 41 can comprise an electromagnet or permanent magnet device making it possible to apply a local magnetic field. FIG. 2B illustrates a nucleation member 41 configured to apply a local magnetic field, which is associated with the presence of an intrinsic defect 42 in the magnetic material, or one created intentionally. The creation of a defect 42 in the upstream chamber 21 thus serves as a preferred center to facilitate nucleation. This defect 42 can be created, in particular, by a local modification of the properties of the magnetic layer by different means such as: a laser beam, a FIB beam (for Focused Ion Beam), or an optical or electron lithography step followed by an etching step. FIG. 2C illustrates a nucleation member 41 configured to apply a local magnetic field when associated with the presence of a magnetic layer 44 attached to the magnetic component 20. A non-magnetic layer 46 may or may not be interposed between the magnetic component 20 and the magnetic layer 44. This magnetic layer 44, or this stack of layers 44 and 46, may have planar magnetic anisotropy. FIG. 2D illustrates a nucleation member 41 configured to apply a local or global magnetic field associated with local heating. The nucleation member 41 may then comprise a local heating device 47 configured to generate such local heating by means of an electric current, a localized laser beam, or any other means. FIG. 2E illustrates a nucleation member 41 configured to apply a local magnetic field in the presence of a local electric field. In this case, the electric field can be used to lower the magnetic anisotropy barrier. Finally, FIG. 2F illustrates a nucleation member 41 configured to inject a spin-polarized current, for example, by defining a pillar of a magnetic stack of the magnetic tunnel junction or spin valve type on the upstream chamber 21. The current is then injected as represented in FIG. 2F. It is understood that these different forms of the nucleation member 41 are not exhaustive.

According to one form, the initialization unit 40 comprises an expansion member 43 configured to move the magnetic domain wall P to the junction member 30, so as to place the magnetic component 20 in the initial magnetic configuration C1. Thus, it is possible to place the conversion device 10 in a configuration in which a physical excitation generated by the excitation unit 50, described below, only contributes to moving the magnetic domain wall P beyond the junction member 30 into the downstream chamber 23. According to a first variant, the expansion member 43 is configured to move the magnetic domain wall P in the direction of propagation X, for example, once the nucleation member 41 has formed a nucleation region. According to another variant, it is possible that the expansion member 43 is configured to move the magnetic domain wall P in the opposite direction to the direction of propagation X, for example to return the magnetic domain wall P to the level of the junction member 30 when it has moved inside the downstream chamber 23. The arrangements described above therefore allow the expansion member 43 to replace the magnetic component 20 in the initial magnetic configuration C1.

Different variants can be used to implement the expansion member 43. According to a first variant, the expansion member 43 comprises a magnetic field generator, such as an electromagnet or permanent magnet device, making it possible to apply a local magnetic field. According to a second variant, the expansion member 43 comprises a spin-polarized current generator. It is also possible for the expansion member 43 to comprise the nucleation member 41.

The conversion device 10 further comprises an excitation unit 50 configured to generate a physical excitation in order to excite the magnetic material, so as to move the magnetic domain wall P in the direction of propagation X, the physical excitation being generated as a function of the initial signal SI. For example, the physical excitation corresponds to a signal comprising electric current pulses or magnetic field pulses. For this purpose, the excitation unit 50 may comprise a current generator 51 configured to generate an electric current, or a magnetic field generator.

According to one form, the initialization unit 40 comprises the excitation unit 50, the excitation unit 50 then being configured to move the magnetic domain wall P up to the junction member 30, so as to place the magnetic component 20 in the initial magnetic configuration C1. In other words, the excitation unit 50 comprises the expansion member 43.

According to one form, the excitation unit 50 may be configured to place the magnetic component 20 in the initial magnetic configuration C1 when the magnetic domain wall P has passed beyond the junction member 30 and is positioned in the downstream chamber 23.

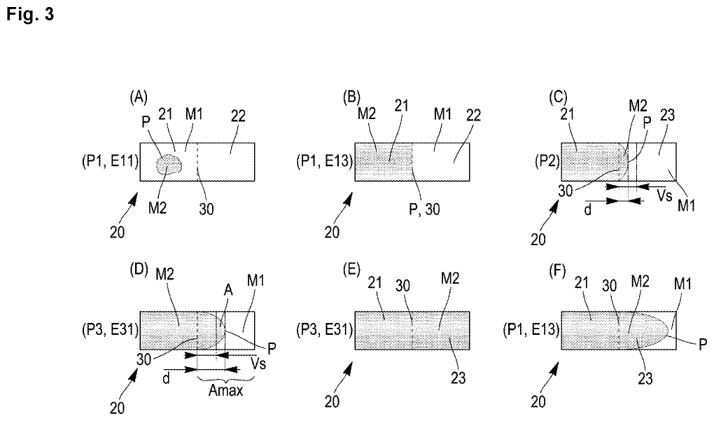

Synergistically, the use of a current generator 51 as the excitation unit 50 in a conversion device 10 comprising only two chambers 21, 23 makes it possible to reduce the energy consumption of the system while maintaining good conversion quality of the initial signal SI by the conversion device 10. Furthermore, the current generator 51 may act both as the expansion member 43 and as the excitation unit 50. FIG. 3 illustrates the conversion device 10 according to different configurations. FIG. 3A shows the conversion device 10 when the magnetic component 20 is in the nucleation configuration C0. FIG. 3B shows the conversion device 10 when the magnetic component 20 is in the initial configuration C1. The current generator 51 may be configured to: inject an electric current to move the magnetic domain wall P in the propagation direction X in order to switch the magnetic component 20 from the nucleation magnetic configuration C0 to the initial magnetic configuration C1; inject an electric current to move the magnetic domain wall P in the propagation direction X beyond the junction member 30; inject a reverse electric current to move the magnetic domain wall P in a direction opposite to the propagation direction X, in order to return the magnetic domain wall P to the level of the junction member 30, in the initial magnetic configuration C1.

Thus, the three functions are fulfilled by a single element.

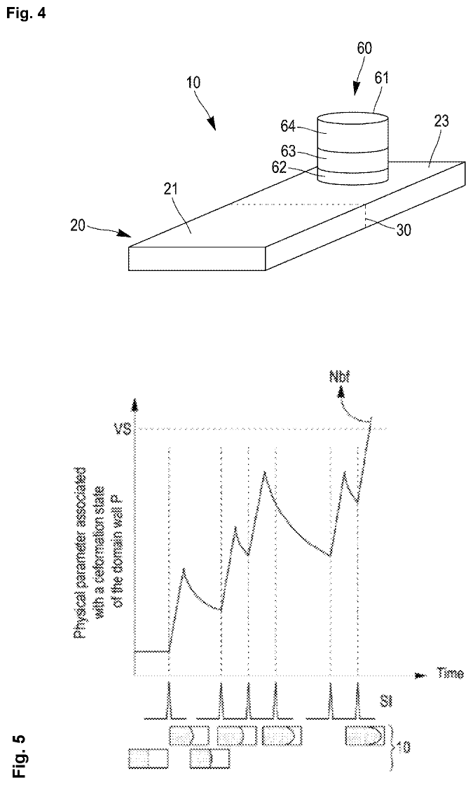

The conversion device 10 further comprises a detection unit 60 arranged at the level of the downstream chamber 23. The detection unit 60 is configured to detect and record at least one characteristic triggering parameter denoted “Nbf” when a physical parameter associated with a deformation state of the magnetic domain wall P exceeds a predetermined threshold value denoted “Vs”. Different variants may be used for implementing the detection unit 60. According to a first variant, the detection unit 60 comprises an optical detector such as a wide-field or focused Kerr-effect optical microscope. FIG. 4 illustrates a second variant in which the detection unit 60 operates by electrical detection. In this case, the detection unit 60 may electrically detect the at least one triggering parameter by means of a magnetic tunnel junction (tunnel magnetoresistance signal), or a spin valve (giant magnetoresistance signal). More specifically, the detection unit 60 may comprise a pillar 61 arranged on the magnetic component 20 vertically above the downstream chamber 23. It is not necessary for this pillar 61 to be centered on the downstream chamber 23. Indeed, and advantageously, the position of the pillar 61 relative to the junction member 30 contributes to defining the predetermined threshold value Vs. According to one form, the pillar 61 may comprise a spin-valve-type stack or a magnetic-tunnel-junction-type stack comprising: a contact electrode 62 for reading the electrical signal; a layer 63 of an insulating material (for example MgO, AlOx, HfO2, etc. in the case of a magnetic tunnel junction stack), or of a non-ferromagnetic electrically conductive material in the case of a spin-valve-type stack; a layer of a magnetic stack 64 constituting the reference magnetic electrode.

According to a first variant, the contact electrode 62 is a magnetic layer magnetically coupled to the magnetic material constituting the magnetic component 20, the local magnetic state then being read at the level of the spin-valve-type stack or the magnetic-tunnel-junction-type stack. Alternatively, the magnetic layer 62 may be omitted. The layer 63 of insulating material, in the case of a magnetic tunnel junction, or the layer 63 of non-ferromagnetic electrically conductive material, in the case of a spin-valve-type stack, is directly deposited on the magnetic material constituting the magnetic component 20. The local magnetic state is then read at the level of the spin-valve-type stack or the magnetic-tunnel-junction-type stack.

The detection unit 60 may also comprise an electrical device allowing to read the resistance of the pillar 61, as well as contacts not shown in FIG. 4.

According to one form, the physical parameter associated with a deformation state of the magnetic domain wall P is a distance denoted “d” measured in the propagation direction X from the junction member 30, the characteristic triggering parameter Nbf being detected and recorded by the detection unit 60 when this distance d exceeds a predetermined threshold distance VS. FIGS. 3C-3F illustrate the conversion device 10 when the magnetic domain wall P moves in the downstream chamber 23. According to one possibility, the predetermined threshold value Vs is a fixed distance measured between the junction member 20 and a position in the downstream chamber 23, as illustrated in FIGS. 3C and 3D. In this case, a triggering parameter Nbf may be detected when the magnetic domain wall P exceeds this fixed distance VS, as illustrated in FIG. 3D. Since this fixed distance VS is not exceeded in FIG. 3C, no characteristic triggering parameter Nbf is therefore detected.

Alternatively, the physical parameter associated with a deformation state of the magnetic domain wall P may be a surface-area measurement or a surface-area ratio, the characteristic triggering parameter Nbf then being detected and recorded by the detection unit 60 when this surface area or surface-area ratio exceeds the predetermined threshold value Vs. For example, the predetermined threshold value Vs may correspond to a maximum area Amax of the downstream chamber 23, and the physical parameter may correspond to the area A of the region of the downstream chamber 23 that is in the second magnetic state M2, as shown in FIG. 3D. In this case, a characteristic triggering parameter Nbf may then be detected when the entire downstream chamber 23 is in the second magnetic state M2, that is to say, when A=Amax, or when the ratio A/Amax=1, as shown in FIG. 3E.

FIG. 5 is a graph representing the variation of a physical parameter of the magnetic component 20, associated with a deformation state of the domain wall in the downstream chamber 23, as a function of the current pulses generated by the physical excitation of the excitation unit 50.

Whatever the considered variant, the dataset SC comprises said at least one characteristic triggering parameter Nbf. For example, the dataset SC is a number corresponding to the number of times a characteristic triggering parameter Nbf is recorded by the detection unit 60. In other words, the dataset SC is equal to the sum of the detected characteristic triggering parameters Nbf.

In general, the detection unit 60 may comprise a memory configured to store the dataset SC.

According to a non-limiting variant, the excitation unit 50 may be configured to stop, at least temporarily, the physical excitation of the magnetic material when the following condition is met: at least one characteristic triggering parameter Nbf is detected by the detection unit 60. However, it is generally provided that the physical excitation is stopped by the excitation unit 50 only at the temporal end of the initial signal SI.

Advantageously, the initialization unit 40 may be configured to place the magnetic component 20 in the initial magnetic configuration C1 when the following condition is met: the at least one characteristic triggering parameter Nbf is detected by the detection unit 60. Being able to reset the magnetic component 20 by placing it in the initial magnetic configuration C1 after each detection of a characteristic triggering parameter Nbf makes it possible to accelerate the return of the magnetic component 20 to the initial magnetic configuration C1, thereby making it possible for the conversion device 10 to temporally detect a maximum number of characteristic triggering parameters Nbf. Furthermore, this makes it possible to artificially reproduce a conversion device 10 comprising a succession of chambers. FIG. 3F illustrates the conversion device 10 in a configuration in which the initialization unit 40 is in the process of returning the magnetic component 20 to the initial magnetic configuration C1.

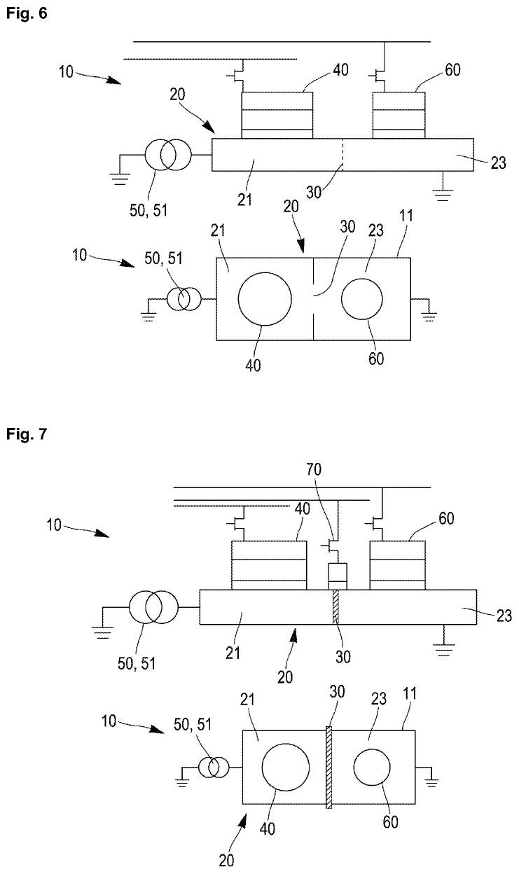

Although the magnetic transmission value Rtr of the junction member 30 may be fixed (as shown in FIG. 6), it is also possible to modify this magnetic transmission value Rtr (as shown in FIG. 7). In this case, and as illustrated in FIG. 7, the conversion device 10 may comprise a reconfiguration unit 70 configured to modify the magnetic transmission value Rtr of the junction member 30. This makes it possible to adapt the junction member 30 to the initial signal SI to be converted. For example, the reconfiguration unit 70 may be configured to modify the magnetic transmission value Rtr of the junction member 30 each time the detection unit 60 detects a characteristic triggering parameter Nbf. Thus, it is possible to modify the magnetic transmission value Rtr of the junction member 30 at the moment when the magnetic component 20 is placed in the initial magnetic configuration C1. This makes it possible to artificially reproduce a succession of chambers separated by junction members 30 having a varying magnetic transmission value Rtr. In other words, the junction member 30 is reconfigurable. There are different variants for reconfiguring junction members 30. In general, the formation of junction members 30 or their reconfiguration is implemented by controlling and modifying the local magnetic properties of the magnetic material constituting the magnetic component 20. The different variants proposed below are different forms enabling one skilled in the art to implement reconfiguration units, and are not limiting.

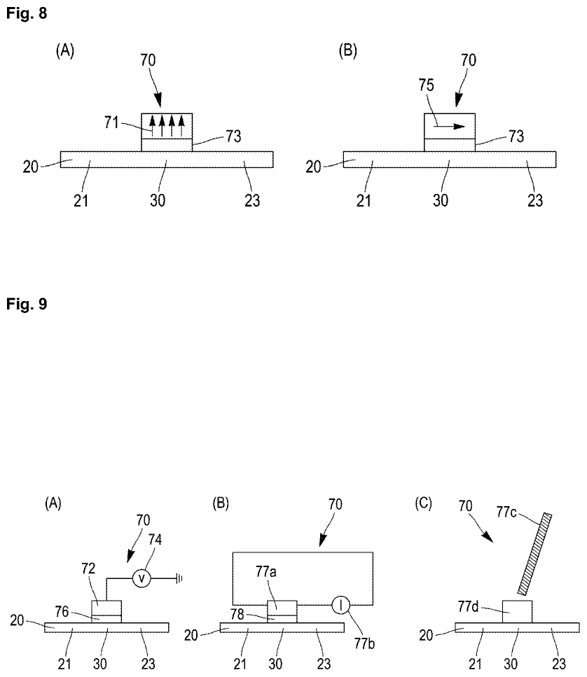

FIGS. 8A-B show a reconfiguration unit 70 capable of modifying the magnetic transmission value Rtr of the junction member 30 by applying a local magnetic field. FIG. 8A more particularly shows a reconfiguration unit 70 configured to apply a local magnetic field by means of a magnetic element 71 whose magnetization is perpendicular to the plane. This magnetic element 71 may be separated from the junction member 30 by a non-magnetic element 73. FIG. 8B shows a reconfiguration unit 70 configured to apply a local magnetic field by means of a magnetic element 75 whose magnetization lies in the plane. This magnetic element 75 may be separated from the junction member 30 by a non-magnetic element 73. Other non-illustrated variants, such as the use of a spin-valve-type structure or a magnetic tunnel junction, may also be used to obtain a reconfiguration unit 70.

One skilled in the art may, for example, refer to European patent application No. 23315104.2 filed on Apr. 25, 2023, in order to obtain a reconfiguration unit 70.

FIG. 9A shows a reconfiguration unit 70 capable of modifying the magnetic transmission value Rtr of the junction member 30 by means of a local electric field produced, for example, by the application of an electrical voltage V. More particularly, the local electric field makes it possible to modulate the magnetic properties of a magnetic layer, in particular its anisotropy and the Dzyaloshinskii-Moriya interaction. FIG. 9A notably shows a conductive electrode 72 to which a voltage V is applied by means of a voltage generator 74. According to this form, a dielectric layer 76 may be interposed between the conductive electrode 72 and the junction member 30.

FIGS. 9B and 9C show a reconfiguration unit 70 capable of modifying the magnetic transmission value Rtr of the junction member 30 by means of a local heating. More specifically, FIG. 9B shows a conductive layer 77a into which an electric current denoted “I” is injected by means of a current generator 77b in order to raise the temperature of the conductive layer 77a by Joule effect. The generated temperature is thus transmitted to the junction member 30 directly, or via an intermediate layer 78 arranged between the junction member and the conductive layer 77a. This intermediate layer 78 may for example be a layer made of a dielectric material, so as to electrically insulate the junction member 30 from the conductive layer 77a into which the current is injected. A local heating may also be achieved by means of a hot tip, for example an atomic force microscopy tip or AFM tip, brought close to the junction member, or by means of a locally focused laser 77c as shown in FIG. 9C. For this purpose, an absorption layer 77d configured to absorb the energy received from the laser 77c may be provided.

All of the arrangements described above make it possible to provide a conversion device 10 capable of converting an initial signal SI into a dataset SC comprising one or more characteristic triggering parameters Nbf. This type of device is particularly suitable for artificial-neuron-type applications. Furthermore, the use of only two chambers 21, 23 makes it possible to obtain a more compact conversion device 10 requiring a lower electrical energy supply.

As indicated previously, the present disclosure also concerns a classification system 1 intended to classify an input signal SE into a signal class denoted “Ci”. An example of such a classification system 1 is shown in FIG. 1.

The classification system 1 comprises: at least one preprocessing device 3 intended to transform the input signal SE into an initial signal SI; at least one conversion device 10 as previously described, receiving said initial signal SI as input and converting the initial signal SI into a dataset SC; an identification unit 5 receiving the dataset SC as input and configured to associate the input signal SE with a signal class Ci as a function of the dataset SC, said signal class Ci being selected from a set of predetermined signal classes stored in a memory 7 of the classification system 1.

The arrangements described above make it possible to provide a classification system 1 capable of classifying an input signal SE as a function of the response detected by the conversion device 10.

According to a non-illustrated variant, the classification system 1 may comprise at least two conversion devices 10. These different conversion devices 10 may receive the same initial signal SI as input. Alternatively, the conversion devices 10 may each receive a distinct and different initial signal SI, said initial signal SI being obtained by transforming the same input signal SE by means of a distinct preprocessing device 3 associated with each of the conversion devices 10. In this manner, it is possible to improve the quality of classification of the input signal SE into a dataset SC. It is also possible to perform at least two conversions of the initial signal SI into a dataset SC in order to improve the signal conversion.

According to a first possibility, the classification system 1 may comprise a preprocessing device 3 capable of converting the input signal SE into a plurality of distinct or non-distinct initial signals SI. Each initial signal SI of the plurality of initial signals SI is then associated with one of the conversion devices 10. Thus, it is possible to obtain different datasets SC from each of the conversion devices 10. According to a second possibility, the classification system 1 may comprise several preprocessing devices 3 each intended to convert the input signal SE into an initial signal SI. It is therefore clearly understood that, for each of the conversion devices 10, it is possible to obtain different initial signals SI from a single input signal SE.

The present disclosure also concerns a method for converting an initial signal SI into a dataset SC. In general, the initial signal SI and the physical excitation are time-dependent. In this case, provision may be made for the conversion method to be stopped at the temporal end of the physical excitation. This conversion method is implemented by a conversion device 10 as described above. FIGS. 3 and 10 to 12 show different phases and steps of the conversion method.

The conversion method comprises an initialization phase P1.

According to one form, the initialization unit 40 of the conversion device 10 may comprise a nucleation member 41. In this case, the initialization phase P1 may comprise a nucleation step E11, in which the nucleation member 41 places the magnetic component 20 in the nucleation magnetic configuration C0 in which all regions of the magnetic component 20 are placed in the first magnetic state M1, except for a nucleation region which is placed in the second magnetic state M2, said nucleation region being contained in the upstream chamber 21. Thus, it is possible to prepare the conversion device 10 to perform a conversion, particularly when it has not been used for a long time.

The initialization phase P1 also comprises an initial step E13 in which the magnetic component 20 is placed in the initial magnetic configuration C1. In the case where a nucleation step E11 is implemented, the initialization unit 40 may for example be configured to place the magnetic component 20 in the initial magnetic configuration C1, for example via the expansion member 43. For example, the initial magnetic configuration C1 corresponds to a configuration in which the inhomogeneous magnetic material is in the second magnetic state M2 in the upstream chamber 21, and in the first magnetic state M1 in the downstream chamber 23, or vice versa.

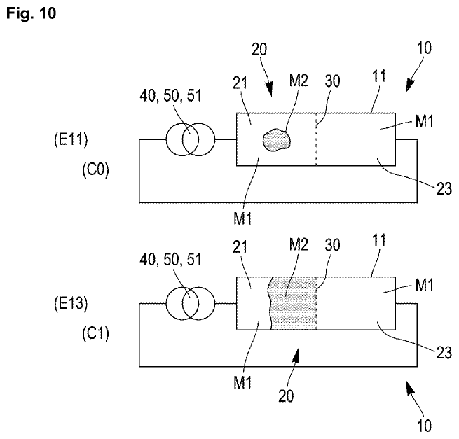

The conversion method also comprises an excitation phase P2 in which the excitation unit 50 generates the physical excitation as a function of the initial signal SI, so as to move the magnetic domain wall P. As illustrated in FIG. 10, the initial step E13 may be implemented simultaneously with the excitation phase P2. In other words, it is the physical excitation generated during the excitation phase P2 that makes it possible to move the magnetic domain wall P toward the junction member 30 so as to switch from the nucleation magnetic configuration C0 to the initial magnetic configuration C1.

The conversion method also comprises a reconfiguration phase P3 implemented if the detection unit 60 detects that the at least one physical parameter associated with the deformation state of the magnetic domain wall P exceeds the predetermined threshold value Vs. The reconfiguration phase P3 then comprises a detection step E31 in which the detection unit 60 records at least one characteristic triggering parameter Nbf in the dataset SC. It is therefore clearly understood that the excitation phase P2 is implemented continuously, and that several detection steps E31 may be implemented, in particular each time the at least one physical parameter associated with the deformation state of the magnetic domain wall P exceeds the predetermined threshold value Vs. According to a first variant, the detection step may be implemented when the magnetic material present in the downstream chamber 23 is entirely in the second magnetic state M2. Thus, the detection of the exceeding of the predetermined threshold value Vs by the physical parameter associated with the deformation of the magnetic wall is simplified. However, such a variant is not limiting, and it is also possible for the detection step E31 to be implemented when the magnetic domain wall P crosses a threshold distance Vs as shown in FIG. 3D.

According to a non-illustrated variant, the reconfiguration phase P3 may comprise a stopping step E32, in which the excitation unit 50 stops, at least temporarily, the implementation of the excitation phase P2; a new excitation phase P2 being implemented at the end of the reconfiguration phase P3. Stopping the excitation phase P2 allows the magnetic component 20 to return to the initial magnetic configuration C1 before the excitation phase P2 is implemented again.

Each time a characteristic triggering parameter is detected during the detection step E31, it is advantageous to implement a new initialization phase P1 at the end of the reconfiguration phase P3. More particularly, once a detection step E31 has been implemented, the initialization unit 40 may return the magnetic component 20 to the initial magnetic configuration C1 by implementing a new initial step E13. It is therefore clearly understood that, according to this form, a new initial step is implemented each time a detection step is implemented. As specified with reference to the conversion device, the initial step E13 may be implemented by the excitation unit 50 when the initialization unit 40 comprises the excitation unit 50. In the particular case where the excitation unit 50 comprises a current generator 51, it is advantageous for the initial steps E13 implemented after the detection steps E31 to be carried out by injection of an electric current by the current generator 51 in a direction opposite to the propagation direction X. It is thus possible to actively return the magnetic component 20 to the initial magnetic configuration C1 in order to save time. It is also clearly understood that the implementation of a nucleation step E11 is independent from the implementation of an initial step E13. For example, the conversion method may comprise a single nucleation step E11 and a plurality of initial steps E13 implemented (actively or otherwise) after each detection step E31.

According to a non-limiting variant in which the conversion device 10 comprises a reconfiguration unit, the reconfiguration phase P3 may also comprise a modification step E33 implemented after the detection step E31, in which the reconfiguration unit 70 modifies the magnetic transmission value Rtr of the junction member 30. In this manner, it is possible to artificially reproduce a succession of chambers separated by junction members having a varying magnetic transmission value Rtr. Such a variant is, for example shown in FIG. 12.

The arrangements described above make it possible to provide a conversion method for converting an initial signal SI into a dataset SC by means of a conversion device 10 that may use only two chambers of a magnetic material.

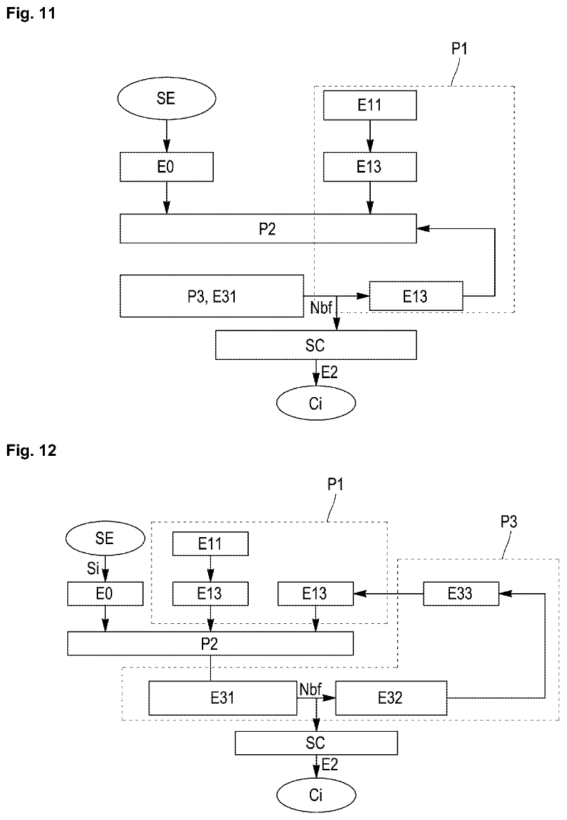

Finally, and as illustrated in FIGS. 11 and 12, the present disclosure concerns a classification method for classifying an input signal SE into a signal class Ci. The classification method is implemented by a classification system 1 as described above and comprises the following steps: a preprocessing step E0 in which the preprocessing device 3 transforms the input signal SE into an initial signal SI; at least one conversion step E1 in which a conversion method as described above is applied by the conversion device 10 to the initial signal SI, so as to obtain a dataset SC corresponding to the initial signal SI; an identification step E2 in which the identification unit 5 associates the input signal SE with a signal class Ci as a function of the dataset SC obtained during the at least one conversion step E1.

The arrangements described above make it possible to provide a method for classifying an input signal SE into a signal class by means of a compact conversion device 10. The classification method may therefore comprise one or more conversion steps E1, depending in particular on the number of conversion devices 10.

According to a non-illustrated variant, in which the classification system 1 comprises N conversion devices 10 (N being an integer greater than or equal to 2), it is possible for the preprocessing step E0 to comprise transformation of the input signal SE into N initial signals SI. For example, these initial signals SI may be different or identical. Each of these initial signals SI may be associated with one of the N conversion devices 10.

Thus, it is possible to adapt the preprocessing step E0 in order to obtain an initial signal either as a function of the conversion device 10 with which it is associated, or as a function of a particular characteristic that it is desired to extract, or both. For example, it is possible to implement the preprocessing step as a function of the magnetic transmission values Rtr of each of the junction members 30 of the N conversion devices 10.

According to this variant, the classification method may comprise N conversion steps E1 implemented by the N conversion devices 10, and the conversion method will make it possible to obtain N datasets SC. The identification step E2 may then consist in associating the input signal SE with a signal class as a function of the N datasets SC obtained during the N conversion steps E1.

Unless otherwise expressly indicated herein, all numerical values indicating mechanical/thermal properties, compositional percentages, dimensions and/or tolerances, or other characteristics are to be understood as modified by the word “about” or “approximately” in describing the scope of the present disclosure. This modification is desired for various reasons including industrial practice, material, manufacturing, and assembly tolerances, and testing capability.

As used herein, the phrase at least one of A, B, and C should be construed to mean a logical (A OR B OR C), using a non-exclusive logical OR, and should not be construed to mean “at least one of A, at least one of B, and at least one of C.”

In this application, the term “controller” and/or “module” may refer to, be part of, or include: an Application Specific Integrated Circuit (ASIC); a digital, analog, or mixed analog/digital discrete circuit; a digital, analog, or mixed analog/digital integrated circuit; a combinational logic circuit; a field programmable gate array (FPGA); a processor circuit (shared, dedicated, or group) that executes code; a memory circuit (shared, dedicated, or group) that stores code executed by the processor circuit; other suitable hardware components (e.g., op amp circuit integrator as part of the heat flux data module) that provide the described functionality; or a combination of some or all of the above, such as in a system-on-chip.

The term memory is a subset of the term computer-readable medium. The term computer-readable medium, as used herein, does not encompass transitory electrical or electromagnetic signals propagating through a medium (such as on a carrier wave); the term computer-readable medium may therefore be considered tangible and non-transitory. Non-limiting examples of a non-transitory, tangible computer-readable medium are nonvolatile memory circuits (such as a flash memory circuit, an erasable programmable read-only memory circuit, or a mask read-only circuit), volatile memory circuits (such as a static random access memory circuit or a dynamic random access memory circuit), magnetic storage media (such as an analog or digital magnetic tape or a hard disk drive), and optical storage media (such as a CD, a DVD, or a Blu-ray Disc).

The apparatuses and methods described in this application may be partially or fully implemented by a special purpose computer created by configuring a general-purpose computer to execute one or more particular functions embodied in computer programs. The functional blocks, flowchart components, and other elements described above serve as software specifications, which can be translated into the computer programs by the routine work of a skilled technician or programmer.

The description of the disclosure is merely exemplary in nature and, thus, variations that do not depart from the substance of the disclosure are intended to be within the scope of the disclosure. Such variations are not to be regarded as a departure from the spirit and scope of the disclosure.

What is claimed is:

1. A conversion device for converting an initial signal (SI) into a dataset (SC) for an artificial neuron application, the conversion device comprising:
a magnetic component comprising a magnetic material configured to vary locally between a first magnetic state (M1) having a first magnetization, and a second magnetic state (M2) having a second magnetization different from the first magnetization, said magnetic component being subdivided into a plurality of regions, wherein each region is either in the first magnetic state (M1) or in the second magnetic state (M2); each region in the first magnetic state (M1) being separated from a region in the second magnetic state (M2) by a magnetic domain wall (P);
a junction member separating the magnetic component into an upstream chamber and a downstream chamber and providing a magnetic communication between the upstream chamber and the downstream chamber, said junction member being characterized by a magnetic transmission value (Rtr) corresponding to a capability of the junction member to allow a displacement of the magnetic domain wall (P) in a propagation direction (X), said propagation direction (X) being defined from the upstream chamber toward the downstream chamber;
an initialization unit configured to place the magnetic component in an initial magnetic configuration (C1), in which the magnetic domain wall (P) is arranged at a level of the junction member;
an excitation unit configured to generate a physical excitation in order to excite the magnetic material, so as to move the magnetic domain wall (P) in the propagation direction (X), the physical excitation being generated as a function of the initial signal (SI); and
a detection unit arranged at a level of the downstream chamber, said detection unit being configured to detect and record at least one characteristic triggering parameter (Nbf) when a physical parameter associated with a deformation state of the magnetic domain wall (P) exceeds a predetermined threshold value (Vs), the dataset (SC) comprising said at least one characteristic triggering parameter (Nbf).

2. The conversion device according to claim 1, further comprising a closed-contour peripheral boundary within which the magnetic component is entirely contained.

3. The conversion device according to claim 1, wherein the initialization unit is configured to place the magnetic component in the initial magnetic configuration (C1) when the following condition is satisfied: the at least one characteristic triggering parameter (Nbf) is detected by the detection unit.

4. The conversion device according to claim 1, wherein the initialization unit comprises an expansion member configured to move the magnetic domain wall (P) up to the junction member, so as to place the magnetic component in the initial magnetic configuration (C1).

5. The conversion device according to claim 1, further comprising a reconfiguration unit configured to modify the magnetic transmission value (Rtr) of the junction member.

6. The conversion device according to claim 1, wherein the excitation unit comprises a current generator configured to generate an electric current.

7. A classification system to classify an input signal (SE) into a signal class (Ci), the classification system comprising:
at least one preprocessing device intended to transform the input signal (SE) into at least one initial signal (SI);
at least one conversion device according to claim 1, receiving as input an initial signal (SI) from among said at least one initial signal (SI) and converting said received initial signal (SI) into a dataset (SC); and
an identification unit receiving the dataset (SC) as input and configured to associate the input signal (SE) with a signal class (Ci) as a function of the dataset (SC), said signal class (Ci) being selected from a set of predetermined signal classes stored in a memory of the classification system.

8. A method for converting an initial signal (SI) into a dataset (SC) for an artificial neuron application, the method being implemented by a conversion device according to claim 1, and the method comprising:
an initialization phase (P1) comprising an initial step (E13) in which the magnetic component is placed in the initial magnetic configuration (C1);
an excitation phase (P2) in which the excitation unit generates the physical excitation as a function of the initial signal (SI), so as to move the magnetic domain wall (P); and
a reconfiguration phase (P3) implemented if the detection unit detects that the at least one physical parameter associated with the deformation state of the magnetic domain wall (P) exceeds the predetermined threshold value (Vs), the reconfiguration phase (P3) then comprising a detection step (E31) in which the detection unit records at least one characteristic triggering parameter (Nbf) in the dataset (SC).

9. The method according to claim 8, wherein the initialization unit comprises a nucleation member, the initialization phase (P1) then comprising a nucleation step (E11), implemented before the initial step (E13), in which the nucleation member places the magnetic component in a nucleation magnetic configuration (C0) in which all regions of the magnetic component are placed in the first magnetic state (M1), except for a nucleation region which is placed in the second magnetic state (M2), said nucleation region being contained in the upstream chamber.

10. The method according to claim 8, wherein the reconfiguration phase (P3) comprises a stopping step (E32), in which the excitation unit stops, at least temporarily, the implementation of the excitation phase (P2); a new excitation phase (P2) being implemented at an end of the reconfiguration phase (P3).

11. The method according to claim 8, wherein a new initialization phase (P1) is implemented at an end of the reconfiguration phase (P3).

12. The method according to claim 8, implemented by a conversion device according to claim 5, wherein the reconfiguration phase (P3) further comprises a modification step (E33) implemented after the detection step (E31), in which the reconfiguration unit modifies the magnetic transmission value (Rtr) of the junction member.

13. A classification method for classifying an input signal (SE) into a signal class (Ci), the classification method being implemented by a classification system according to claim 7 and comprising:
a preprocessing step (E0) in which the preprocessing device transforms the input signal (SE) into at least one initial signal (SI);
at least one conversion step (E1) in which a conversion method according to any one of claims 8 to 12 is applied by the conversion device to an initial signal (SI) from among said at least one initial signal (SI), so as to obtain a dataset (SC) corresponding to said initial signal (SI) to which the conversion method is applied; and
an identification step (E2) in which the identification unit associates the input signal (SE) with a signal class (Ci) as a function of the dataset (SC) obtained during the at least one conversion step (E1).
